(19) United States
(12) Patent Application Publication
(10) Pub. No.: US 2007/0057378 A1
(43) Pub. Date: Mar. 15, 2007

(54) Electronic device and manufacturing method therefor

(75) Inventors: Kazuhisa Arai, Tokyo (JP); Masaru Nakamura, Tokyo (JP)

Correspondence Address: BRINKS HOFER GILSON & LIONE, P.O. BOX 10395, CHICAGO, IL, 60610, US

(73) Assignee: DISCO CORPORATION

(21) Appl. No.: 11/519,321

(22) Filed: Sep. 12, 2006

(30) Foreign Application Priority Data
Sep. 13, 2005 (JP) 2005-265477

(51) Int. Cl. H01L 23/52

(52) U.S. Cl. 257/777

(57) ABSTRACT

On the back surface of the chip of which a front surface is formed with an electronic circuit, an adhesive film of a shape and dimensions corresponding to at least the back surface of the chip is adhered to obtain the semiconductor chip with the entire back surface covered with the adhesive film. Such a semiconductor chip is obtained by forming a division groove in the front surface of a semiconductor wafer to be divided into plural chips, grinding a back surface of the wafer until the division groove appears to divide the wafer into plural chips, adhering the adhesive film and a dicing tape on the entire back surface of the wafer, and stretching the dicing tape to cut the adhesive film along the division groove.

This application claims priority under 35 U.S.C. § 119 to Japanese Patent Application No. JP2005-265477 filed Sep. 13, 2005, the entire content of which is hereby incorporated by reference.

### BACKGROUND OF THE INVENTION

1. Field of the Invention

The present invention relates to a technique relating to a device such as a semiconductor chip, and in particular, relates to a device on a back surface of which an adhesive film is adhered, and to a manufacturing method for the device.

2. Related Art

In recent techniques for semiconductor devices, a stacked package such as an MCP (Multi-Chip Package) and a SiP (System in Package), in which a plurality of semiconductor chips are stacked, is used effectively in order to achieve high density and miniaturization. On a back surface of the semiconductor chip provided in such a technique, an adhesive film called a DAF (Die Attach Film), which is made of resin is adhered. With this adhesive film, the stacked state of the semiconductor chips is maintained. As a method for manufacturing the semiconductor chip on the back surface of which the adhesive film is adhered, there is a method in which the adhesive film is adhered on a back surface of a thinned semiconductor wafer, and the semiconductor wafer is divided along predetermined division lines called “streets” in the shape of a lattice while cutting the adhesive film (Japanese Patent Application Laid-open No. 2004-319829).

In this type of semiconductor chip, mold resin is filled in a periphery of the semiconductor chip after the chip is mounted on a mounting board in many cases. However, if the adhesive film does not cover the entire back surface of the semiconductor chip, and if a small part of an edge of the back surface is exposed, for example, a filler material included in the mold resin and called “filler” (with a particle diameter of about 10 to 20 μm and including silica, for example) may damage the exposed face on which the adhesive film is not adhered or may be pushed into a small gap between the exposed face and the stacked object, thereby causing cracking or chipping of the semiconductor chips. Especially in the extremely thin semiconductor chips having thicknesses of 100 μm or less, such a problem is likely to occur.

Furthermore, the adhesive film also functions as an insulating material in some cases. In this case, if the back surface includes the exposed face which is not covered with the adhesive film as described above, the exposed portion may come into contact with a bonding wire of the semiconductor chip on the stacked object side, thereby causing electrical problems such as short circuiting and leakage. Therefore, it is preferable that the entire back surface of the semiconductor chip be covered with the adhesive film.

### SUMMARY OF THE INVENTION

Therefore, it is an object of the present invention to provide a device with a two-layered structure in which an adhesive film is adhered on a back surface of a chip such as a semiconductor chip, the device having a structure in which the entire back surface of the chip is covered with the adhesive film, and to provide a manufacturing method for the device.

According to the present invention, there is provided a device with a two-layered structure which includes a chip having a functional element on a front surface of the chip and an adhesive film adhered on a back surface of the chip, in which the adhesive film corresponds to at least the back surface of the chip and covers the entire back surface, and an outer periphery of the chip does not protrude from an outer periphery of the adhesive film.

With the device of the present invention, the entire back surface of the chip is protected by the adhesive film. Therefore, even if mold resin is filled in a periphery of the device, filler included in the mold resin does not enter the back surface of the chip, thereby avoiding problems such as damage to the chip by the filler. If the devices of the invention are stacked, the back surface of the chip is prevented from coming into contact with a bonding wire of the device on the stacked side because the adhesive film is interposed. Therefore, electrical problems such as short circuiting and leakage are prevented.

In the device of the invention, it is essential that the entire back surface of the chip be covered with the adhesive film. Furthermore, it is preferable that the adhesive film be larger than the back surface of the chip and have an extra portion extending from an edge of the back surface, because the back surface of the chip is further reliably sealed by the adhesive film.

A manufacturing method for the device, according to the present invention, is suitable for producing the above device of the invention and is a manufacturing method for a device with a two-layered structure including a chip having a functional element on the front surface of the chip and the adhesive film adhered on the back surface of the chip from the wafer on which a plurality of function elements is defined by predetermined division lines formed in a lattice shape on the front surface of the wafer, the method including: a division groove forming step for forming a division groove in a front surface of a wafer along a predetermined division line, the division groove having a depth corresponding to a thickness of the chip to be obtained; a protection film adhering step for adhering a protection film on the front surface of the wafer; a back surface grinding step for grinding a back surface of the wafer until the division groove appears to divide the wafer into the individual chips; an adhesive film adhering step for adhering the adhesive film on a back surface of the wafer divided into the plurality of chips and adhering a dicing tape on the adhesive film, the dicing tape supported by an annular frame and being extensible; and an adhesive film cutting step for stretching the dicing tape while retaining the frame to thereby cut the adhesive film along the division groove.

In the above manufacturing method, between the back surfaces of the adjacent chips separated from each other in the back surface grinding step, the adhesive film corresponding to the width of the division groove exists. The adhesive film between the chips is cut, and therefore the adhesive film tends to be cut at a position slightly outward from an edge of the chip. Therefore, the entire back surface of the chip is covered with the adhesive film, and an extra portion extending from the edge of the back surface of the chip is likely to be obtained.

In the manufacturing device of the present invention, instead of stretching the dicing tape as described above, it is possible to obtain the device by employing an adhesive film cutting step for applying a laser beam to the adhesive film through the division groove to thereby cut the adhesive film along the division groove after the adhesive film adhering step.

With the present invention, it is possible to obtain a device in which the entire back surface of a chip is reliably covered with an adhesive film. Therefore, it is possible to provide a device of high quality in which damage to the chip and electrical problems caused by exposure of a part of the back surface of the chip are prevented.

### BRIEF DESCRIPTION OF THE DRAWINGS

FIG. 1 is a general perspective view of a semiconductor wafer to be divided into semiconductor chips, and an enlarged portion is a device region.

FIG. 2 is a schematic side view of a division groove forming step in a manufacturing method according to a first embodiment of the invention.

FIG. 3 is a general perspective view of a dicing device used in the division groove forming step.

FIG. 4 is a perspective view of a front surface side of the semiconductor wafer after the division groove forming step.

FIG. 5A is a perspective view of a back surface side of the semiconductor wafer on a front surface of which a protection seal is adhered prior to a back surface grinding step, and FIG. 5B is a perspective view of the back surface side of the semiconductor wafer after the back surface grinding step.

FIG. 6 is a schematic side view of the back surface grinding step in the manufacturing method according to the first embodiment.

FIG. 7 is a general perspective view of a grinder used in the back surface grinding step.

FIG. 8 is a side view of the semiconductor wafer on the back surface of which an adhesive film and a dicing tape are adhered and a state in which the semiconductor wafer is set in a dividing device.

FIG. 9 is a side view of a state in which an adhesive film cutting step is carried out by the dividing device shown in FIG. 8.

FIG. 10 is a perspective view of a state in which an adhesive film cutting step is carried out in a manufacturing method according to a second embodiment of the invention and an enlarged portion is a sectional view of a state in which a laser beam is applied to the adhesive film.

FIG. 11 is a schematic side view of a back surface grinding step in a manufacturing method according to a third embodiment of the invention.

FIG. 12 is a schematic side view of an internal modified layer forming step according to the third embodiment.

FIG. 13 is a side view of a state in which an adhesive film and a dicing tape are adhered on the back surface of the semiconductor wafer and a state in which the semiconductor wafer is set in a dividing device in the third embodiment.

FIG. 14 is a side view of a state in which an adhesive film cutting step according to the third embodiment is carried out.

### EMBODIMENTS OF THE INVENTION

Manufacturing methods for the first to third embodiments according to the present invention will be described below with reference to the drawings.

### 1. Manufacturing Method for the First Embodiment

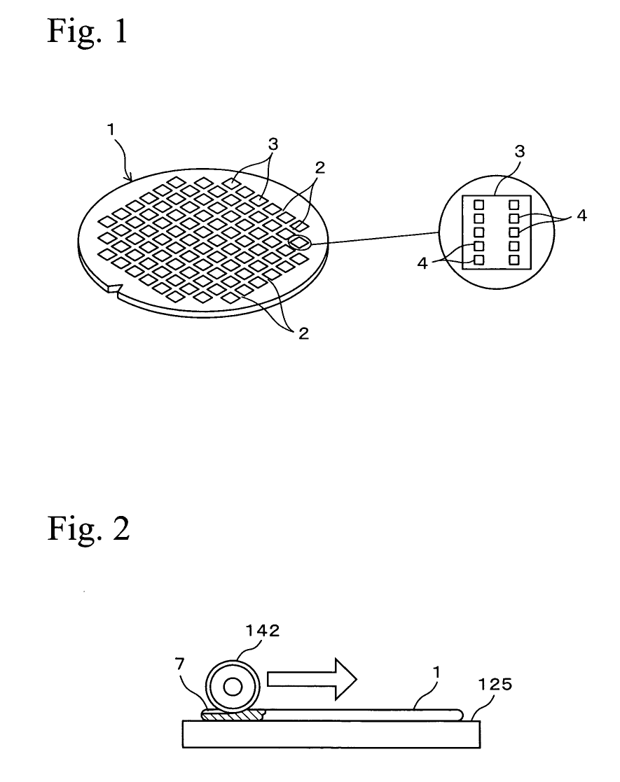

A reference numeral 1 in FIG. 1 designates a disk-shaped semiconductor wafer formed of a silicon wafer or the like. As shown in FIG. 1, on a front surface of the wafer 1, rectangular chip regions 3 are defined by lattice-shaped streets (predetermined division lines) 2. On a front surface of each of these chip regions 3, electronic circuits (functional elements) 4 are formed as shown in an enlarged portion in FIG. 1.

The chip regions 3 are separated from each other by the manufacturing method of the present embodiment, and each of the regions becomes a chip 6 of a semiconductor chip (device) 5 with an adhesive film and which will be described later (see FIG. 9). A thickness of the wafer 1 is greater than a thickness of the chip 6 to be produced. The embodiment is a method for manufacturing the semiconductor chip with a two-layered structure in which an adhesive film such as a DAF is adhered on a back surface of the chip 6; the manufacturing method will be described below in the order of the steps. In the following descriptions, a “front surface” of the wafer 1 or the chip 6 is defined as a face on which the electronic circuits 4 are formed and a “back surface” is defined as a face opposite to this front surface and on which the electronic circuits are not formed.

(1) Division Groove Forming Step

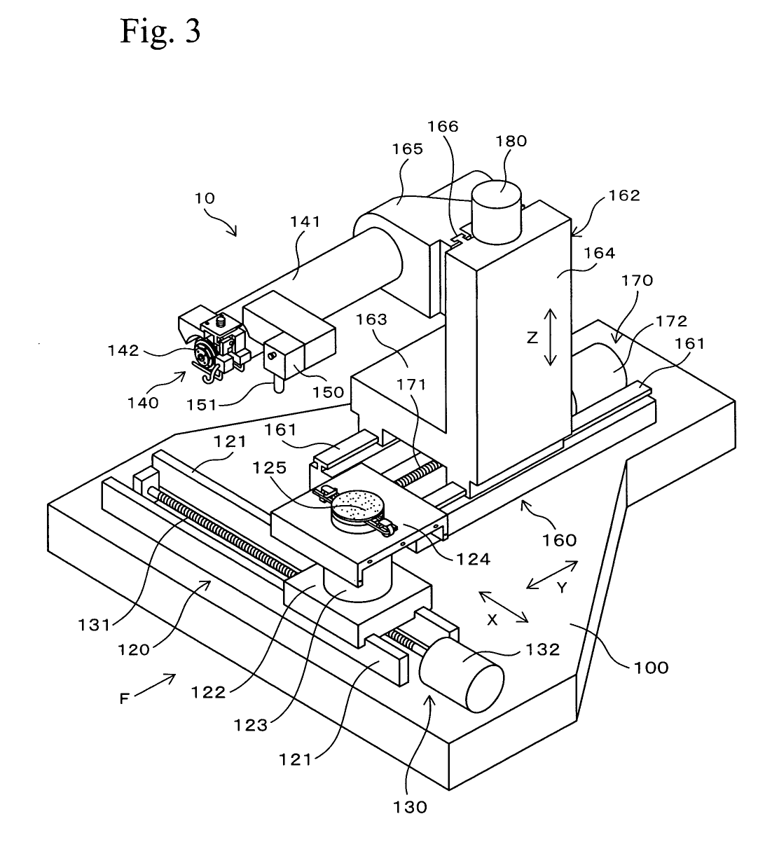

As shown in FIG. 2, the wafer 1 is held on a chuck table 125 with the front surface facing up. Then, division grooves 7 with depths slightly greater than the thickness of the chip 6 to be obtained are formed in a lattice shape along the streets 2 by a cutting blade 142. FIG. 3 shows a dicing device 10 for cutting and dividing the wafer 1 along the streets 2 into semiconductor chips and the division grooves 7 can be formed by this dicing device 10. A method of forming the division grooves 7 by this dicing device 10 will be described below.

First, a structure of the dicing device 10 shown in FIG. 3 will be described. The dicing device 10 includes a base 100. Provided on this base 100 are: a chuck table mechanism 120 for retaining the wafer 1 in a horizontal orientation and moving it in a cutting feed direction (direction X in FIG. 3); a cutting unit 140 for cutting the front surface of the wafer 1 to form division grooves 7; and a cutting unit support mechanism 160 for supporting the cutting unit 140 and moving it in an indexing direction (direction Y in FIG. 3). The cutting unit 140 is mounted to be movable in an entering direction (direction Z in FIG. 3) with respect to the cutting unit support mechanism 160.

The chuck table mechanism 120 is disposed on one end side in the direction Y on the base 100 and includes: a pair of guide rails 121 fixed to the base 100 and extending in the direction X; a moving plate 122 slidably mounted onto the guide rails 121; a stage 124 supported on the moving plate 122 through a cylindrical post 123; a disk-shaped chuck table 125 rotatably mounted onto the stage 124; and a slide mechanism 130 for moving the moving plate 122 along the guide rails 121.

The chuck table 125 has a horizontal upper face and is rotated clockwise or counterclockwise by a rotary driving mechanism (not shown) housed in the post 123. The chuck table 125 is of a known vacuum chuck type. In other words, the chuck table 125 is formed with a large number of small suction holes communicating with the front surface and the back surface, and air suction ports of a vacuum device (not shown) are connected to the back surface side. If the vacuum device is operated, the wafer 1 is suctioned and held on the chuck table 125.

The slide mechanism 130 includes a spiral rod 131 disposed between the base 100 and the moving plate 122 and extending in the direction X, and a pulse motor 132 for driving the spiral rod 131 for rotation. The spiral rod 131 is screwed into and penetrates a bracket (not shown) formed to protrude from a lower face of the moving plate 122, and it is rotatably supported so as not to be movable in an axial direction. With this slide mechanism 130, if the spiral rod 131 is rotated by the pulse motor 132, the moving plate 122 is moved along the guide rails 121 in the direction X according to the rotating direction of the rod 131.

The cutting unit support mechanism 160 includes: a pair of guide rails 161 disposed and fixed on the base 100 and extending in the direction Y to form a T-shape together with the guide rails 121 of the chuck table mechanism 120; a moving table 162 slidably mounted onto the guide rails 161; and a slide mechanism 170 for moving the moving table 162 along the guide rails.

The moving table 162 is an L-shaped table having a horizontal plate portion 163 and a vertical plate portion 164 rising from one end portion in the direction X of the horizontal plate portion 163 (i.e., right end portion in a view along an arrow F in FIG. 3 and in which the cutting unit 140 is seen along the direction Y from the end portion on the chuck table mechanism 120 side of the base 100 in this case). A lower face of the horizontal plate portion 163 is slidably mounted to the guide rails 161.

The slide mechanism 170 has the same structure as the slide mechanism 130 of the chuck table mechanism 120 and includes a spiral rod 171 disposed between the base 100 and the horizontal plate portion 163 and extending in the direction Y, and a pulse motor 172 for driving this spiral rod 171 for rotation. The spiral rod 171 is screwed into and penetrates a bracket (not shown) formed to protrude from a lower face of the horizontal plate portion 163 and is rotatably supported so as not to be movable in an axial direction. With this slide mechanism 170, if the spiral rod 171 is rotated by the pulse motor 172, the moving table 162 is moved along the guide rails 161 in the direction Y according to a rotating direction of the rod 171.

The cutting unit 140 includes: a cylindrical housing 141 extending in the direction Y; a disk-shaped cutting blade 142 attached to a tip end on the chuck table mechanism 120 side of the housing 141; and an aligner 150 for locating a cutting line along which cutting is carried out by the cutting blade 142. The cutting unit 140 is mounted to a left face of the vertical plate portion 164 of the moving table 162 in a view along the arrow F so as to be able to move up and down through a housing holder 165.

The housing holder 165 is slidably mounted to a guide rail 166 formed on the left face of the vertical plate portion 164 and extending in the vertical direction. The holder 165 is raised and lowered along the guide rail 166 by a raising and lowering mechanism driven by a pulse motor 180 fixed onto the vertical plate portion 164. The housing 141 penetrates and is fixed to the housing holder 165. In this way, the cutting unit 140 can move up and down with the housing holder 165.

In the housing 141, a spindle extending in the direction Y and a motor for rotating the spindle (neither of which are shown) are housed. The cutting blade 142 is fixed to a tip end of the spindle. With an exposed lower portion of the cutting blade 142 rotating with the spindle, the division groove 7 is formed in the front surface of the wafer 1.

The aligner 150 is formed of a microscope, a CCD camera, or the like and has an image pickup portion 151 for capturing an image of a target at a tip end of the aligner 150. The aligner 150 is mounted to a tip end portion of the housing 141 in such a manner that the image pickup portion 151 is adjacent to the cutting feed direction (direction Y) of the cutting blade 142.

Next, an operation for forming the division groove 7 in the front surface of the wafer 1 by using the dicing device 10 having the above structure will be described. The dicing device 10 includes a control means for controlling various operations. First, the wafer 1 with its front surface facing up is placed on the chuck table 125 of the chuck table mechanism 120 and the vacuum device of the chuck table mechanism 120 is operated. As a result, the wafer 1 is suctioned and held on the chuck table 125. Next, the chuck table 125 is moved in the direction Y together with the moving plate 122 by the slide mechanism 130 to position the wafer 1 directly below the image pickup portion 151 of the aligner 150 that has been disposed on a movement line of the chuck table 125 in advance.

Then, an image of the street 2 on the front surface of the wafer 1 is captured by the aligner 150 and the chuck table 125 is rotated by the controller based on the captured image to align the wafer 1 with the cutting blade 142 so that the street 2 extending in one direction becomes parallel to the direction Y (i.e., a street 2 orthogonal to this street 2 extends in the direction X).

Moreover, with the controller, the image captured by the aligner 150 is subjected to image processing and a cutting operation pattern is determined and stored based on the processed image. The cutting operation pattern is a combination of an entering feed of the cutting blade 142 by movement of the cutting unit 140 in the direction Z, a cutting feed of the cutting blade 142 by movement of the chuck table 125 in the direction X, and indexing of the cutting blade 142 by movement of the cutting unit 140 in the direction Y for forming the division groove 7 of a slightly greater depth than the thickness of the chip 6 to be obtained in every street 2. An entering depth of the cutting blade 142 is set to a value slightly greater than the thickness of the chip 6 to be obtained as described above.

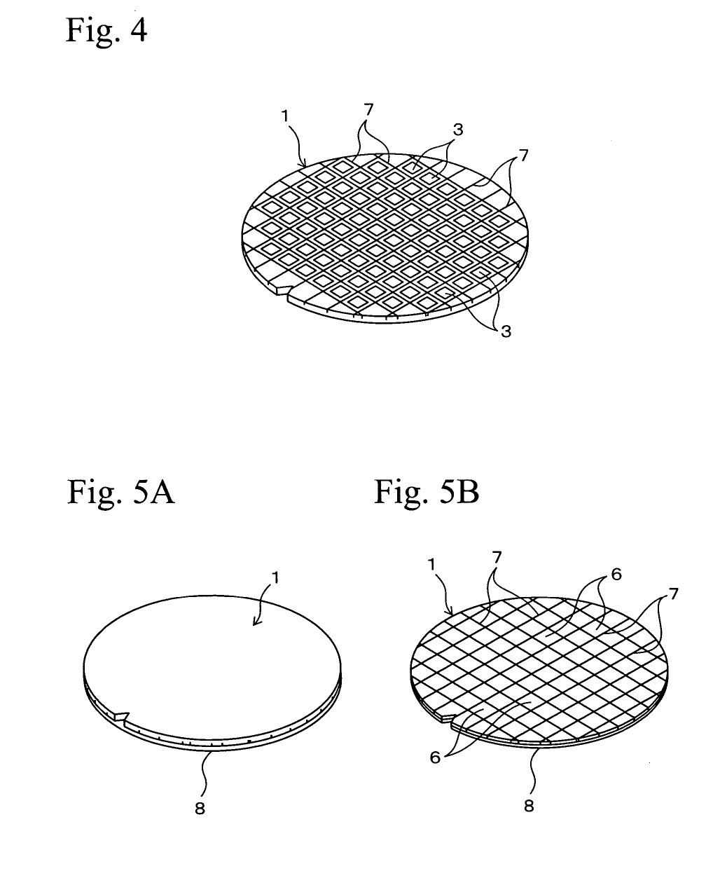

By means of the controller, the slide mechanisms 130 and 170 and the raising and lowering mechanism driven by the pulse motor 180 are actuated to follow the above stored cutting operation pattern. With the rotating cutting blade 142, the division grooves 7 along the streets 2 extending in the lattice shape are formed in the front surface of the wafer 1 as shown in FIG. 4.

The division grooves 7 are first formed along the streets 2 extending in the direction Y by alternately repeating movement of the chuck table 125 in the direction Y and movement of the moving table 162 in the direction X. Next, the chuck table 125 is rotated 90°. Then, by alternately repeating movement of the chuck table 125 in the direction Y and movement of the cutting unit support mechanism 160 in the direction X again, the division grooves 7 are formed along the streets 2 orthogonal to the streets 2 along which the division grooves 7 have been formed already. Thus, the wafer 1 in the front surface of which the division grooves 7 are formed along all the streets 2 shown in FIG. 4 is obtained.

(2) Protection Film Adhering Step

On the entire front surface of the wafer 1 in which the division grooves 7 have been formed in the above manner, a protection film 8 is adhered as shown in FIG. 5A. With this protection film 8, the electronic circuits 4 on the front surface are protected.

(3) Back Surface Grinding Step

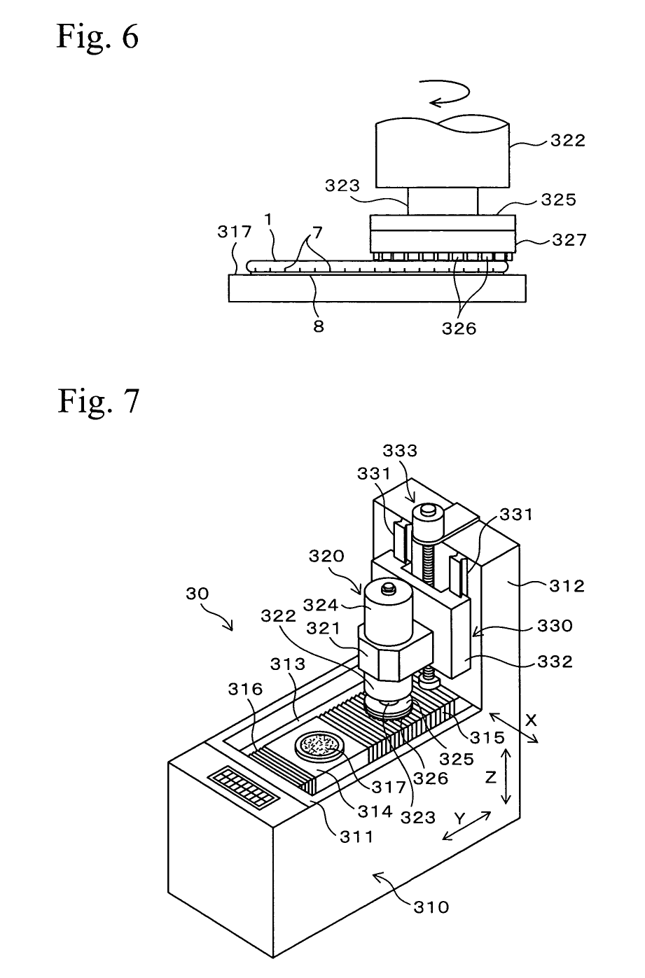

Next, a back surface grinding step for grinding the back surface of the wafer 1 to reach the division grooves 7 to separate the chip regions 3 as individual chips 6 is carried out. For this step, as shown in FIG. 6, the protection film 8 is brought into close contact with a front surface of a chuck table 317 to hold the wafer 1 on the chuck table 317. Then, the exposed entire back surface of the wafer 1 is ground with grindstones 326 of a grinding wheel 327 until the division grooves 7 appear. FIG. 7 shows a grinding device 30 suitable for grinding the back surface of the wafer 1, and a method for grinding the back surface of the wafer 1 by using the grinding device 30 will be described below.

First, a structure of the grinding device 30 shown in FIG. 7 will be described. The grinding device 30 includes a base 310 on which various mechanisms are mounted. The base 310 includes a table 311 in a shape of a rectangular parallelepiped which is disposed to be horizontally long so as to form a main body of the base 310 and a wall portion 312 extending in a width direction of the table 311 and vertically upward from one end portion in a longitudinal direction of the table 311 (end portion on the back side in FIG. 7). In FIG. 7, the longitudinal direction, the width direction, and the vertical direction of the base 310 are represented by the directions Y, X, and Z, respectively.

In an upper face of the table 311, a recessed area 313 is formed, and a stage 314 is provided for reciprocation in the direction Y in this recessed area 313. On opposite sides of a moving direction of the stage 314, bellows covers 315 and 316 for closing a moving path of the stage 314 to prevent grinding swarf from falling in the base 310 are provided. The stage 314 is caused to reciprocate in the direction Y by a driving mechanism (not shown) and the covers 315 and 316 expand and contract as the stage 314 moves.

On the stage 314, a chuck table 317 of the vacuum chuck type, which is similar to the chuck table 125 of the dicing device 10, is rotatably provided. The chuck table 317 is moved together with the stage 314 toward the wall portion 312 and is positioned in a machining area. Above the machining area, a grinding unit 320 is disposed.

The grinding unit 320 is supported through a feed mechanism 330 to be able to move up and down in the direction Z with respect to the wall portion 312. The feed mechanism 330 includes a pair of guide rails 331, a moving plate 332 for sliding along these guide rails 331, and a raising and lowering mechanism 333 for raising and lowering the moving plate 332 along the guide rails 331.

The grinding unit 320 includes a block 321 affixed to a front surface of the moving plate 332, a cylindrical housing 322 affixed to the block 321, a spindle 323 supported in the housing 322, and a servomotor 324 for driving the spindle 323 for rotation. To a lower end of the spindle 323, a disk-shaped wheel mount 325 is affixed. Moreover, to a lower face of this wheel mount 325, the grinding wheel 327, to a lower face of which a large number of chip-shaped grindstones 326 made of resin bond or the like are secured is affixed, as shown in FIG. 6. Although an outside diameter of the grinding wheel 327 is slightly greater than half of a diameter of the wafer 1 in FIG. 6, the dimension is not limited to this. The grinding unit 320 and the chuck table 317 are disposed in such positions that rotation centers of both of them are arranged in the direction Y.

Next, the operation for grinding the back surface of the wafer 1 by using the grinding device 30 having the above structure will be described, the protection film 8 having been adhered on the front surface of the wafer 1. First, the wafer 1 is placed on the chuck table 317 with its back surface to be ground facing up, and the vacuum device is operated to hold the wafer 1 on the chuck table 317. Then, the stage 314 is moved to move the wafer 1 into the machining area below the grinding unit 320. In this case, the stage 314 is moved to a position such that at least a part of the wafer 1 on the wall portion 312 side and corresponding to a radius of the wafer 1 overlaps the grinding wheel 327.

From this state, the chuck table 317 is rotated to rotate the wafer 1. At the same time as this, the grinding wheel 327 of the grinding unit 320 is rotated by the servomotor 324 and the grinding unit 320 is slowly lowered at a predetermined speed by the feed mechanism 330. The rotating direction of the chuck table 317 may be the same as that of the grindstones 326 or may be the opposite.

As the grinding unit 320 moves down, the grindstones 326 of the rotating grinding wheel 327 press the back surface of the rotating wafer 1 with a predetermined load. Thus, the back surface side of the wafer 1 is ground flat. If grinding of the back surface of the wafer 1 proceeds, the grindstones 326 eventually reach the division grooves 7, and the division grooves 7 appear. If the thickness of the wafer 1 reaches the thickness of the chip 6 to be obtained, the grinding of the back surface is completed. As a result of the grinding of the back surface, the wafer 1 is divided into a plurality of chips 6 as shown in FIG. 5B. However, because the chips 6 are connected to each other through the protection film 8, they are not separated from each other.

(4) Adhesive Film Adhering Step

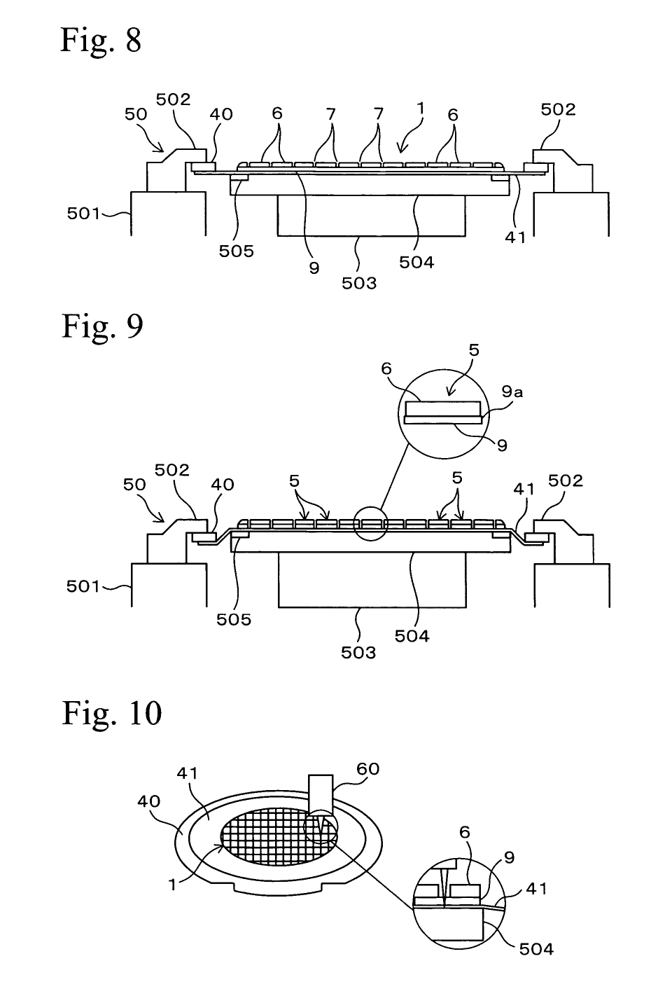

Next, an adhesive film 9 is adhered on the back surface of the wafer 1 in which the plurality of chips 6 obtained by division are connected to each other by the protection film 8 as shown in FIG. 8, and a dicing tape 41 placed and supported on an inside of an annular frame 40 is adhered on the adhesive film 9. The adhesive film 9 is made of adhesive material having adhesion on opposite faces. As the adhesive material, a mixture obtained by properly mixing an additive such as an inorganic filler into a mixture as a base and a thermoplastic polyimide resin with a glass transition temperature (Tg) of 90° C. or less and a thermosetting resin such as an epoxy resin is preferably used, for example.

As the dicing tape 41, a resin tape which is extensible is used. For example, tape formed by applying an acrylic resin adhesive having a thickness of about 5 μm to one face of a polyvinyl chloride sheet having a thickness of about 10 μm as a base material is used, for example. The dicing tape 41 is in a circular shape having a larger diameter than that of the adhesive film 9. The frame 40 is adhered on an adhesive side of an outer peripheral portion of the dicing tape 41, and the adhesive side on which the frame 40 is adhered is adhered on the adhesive film 9. Such adhering of the adhesive film 9 and the dicing tape 41 on the back surface of the wafer 1 can also be achieved by adhering a double-layered tape obtained by integrally forming the adhesive film 9 with the dicing tape 41.

(5) Adhesive Film Cutting Step

Next, an adhesive film cutting step for cutting the adhesive film 9 between the chips 6 to substantially divide the wafer 1 and to yield the semiconductor chips 5 in which the adhesive film 9 is adhered on the back surface of each individual chip 6 is carried out. For this purpose, a dividing device 50 for the wafer 1 shown in FIG. 8 is used. This dividing device 50 includes: a cylindrical base 501; a plurality of retaining chips 502 fixed at regular intervals in a circumferential direction onto an upper end face of the base 501; and a chuck table 504 of a vacuum chuck type which is raised and lowered by a raising and lowering mechanism 503. Each retaining chip 502 protrudes inward so that a gap is created between the retaining chip 502 and the upper end face of the base 501 and the frame 40 can be locked to a lower face of the retaining chip 502. An annular sliding member 505 with a low coefficient of friction is fitted at an outer peripheral edge of an upper end face of the base 501 to be flush with the upper end face of the base. The sliding member 505 is made of a material such as stainless steel having a polished surface, for example.

In order to obtain the semiconductor chip 5 by using the dividing device 50, the wafer 1 is placed on the chuck table 504 with the dicing tape 41 side facing down, and the frame 40 is positioned under the held chips 502 as shown in FIG. 8. Then, the protection film 8 adhered on the front surface is peeled off and removed. From this state, the wafer 1 is raised by the raising and lowering mechanism 503.

In this way, as shown in FIG. 9, the frame 40 is engaged with the retaining chips 502 and further raising is blocked, the dicing tape 41 inside the frame 40 moves up, and as a result, the dicing tape 41 is stretched out radially from the center. As the dicing tape 41 is stretched, the adhesive film 9 between the chips 6 is pulled and is cut along the division grooves 7. At this time, because the outer peripheral edge of the upper face of the chuck table 504 is formed of the sliding member 505, the dicing tape 41 smoothly slides on a corner portion of the outer peripheral edge and is less likely to receive stress, and there is very little risk of breakage of the tape 41.

In the above manner, the semiconductor chip 5 with the two-layered structure in which the adhesive film 9 is adhered on the back surface of the chip 6 as shown in the enlarged portion of FIG. 9 is obtained. The semiconductor chips 5 are still adhered on the dicing tape 41 and are afterwards separated one by one from the dicing tape 41 in an appropriate manner.

In the semiconductor chip 5 manufactured as described above, the entire back surface of the chip 6 is covered with the adhesive film 9, and the back surface is protected by the adhesive film 9. Therefore, when the semiconductor chip 5 is mounted on a mounting board and mold resin is filled in a periphery of the chip, filler included in the mold resin does not enter the back surface of the chip 6, thereby avoiding problems such as damage to the chip 6 by the filler. If the semiconductor chip 5 is applied to a stacked package such as an MCP (Multi-Chip Package) and an SiP (System in Package), the back surface of the chip 6 is prevented from coming into contact with a bonding wire of the semiconductor chip on the stacked side, because the adhesive film 9 is interposed therebetween. Therefore, electrical problems such as short circuiting and leakage are prevented.

Moreover, with the above manufacturing method, between the back surfaces of the adjacent chips 6 separated from each other in the back surface grinding step, the adhesive film 9 corresponding to the width of the division groove 7 exists. The adhesive film 9 between the chips 6 is cut, and therefore the adhesive film 9 tends to be cut in a slightly outer position from an edge of the chip 6 (e.g., a center portion of the width of the division groove 7). Therefore, the entire back surface of the chip 6 is covered with the adhesive film 9 and a surplus portion 9a of the adhesive film 9 extending from the edge of the back surface of the chip 6 is likely to be obtained. Due to the existence of this surplus portion 9a, the adhesive film 9 is larger than the back surface of the chip 6, and the back surface of the chip 6 is further reliably sealed.

### 2. Manufacturing Method for Second Embodiment

Next, a manufacturing method for a second embodiment of the invention will be described. This manufacturing method is the same as that of the first embodiment up until the adhesive film adhering step and differs in the adhesive film cutting step after the adhesive film adhering step. In the adhesive film cutting step in the second embodiment, as shown in FIG. 10, a laser beam is applied to the adhesive film 9 through the division grooves 7 from a laser beam irradiation device 60 to thereby cut the adhesive film 9 along the division grooves 7. In this way, the semiconductor chip 5 in which the adhesive film 9 is adhered on the back surface of the chip 6 is obtained. In order to apply the laser beam to the adhesive film 9 along the division grooves 7, the laser beam irradiation device 60 is mounted in place of the cutting blade 142 of the dicing device 10 shown in FIG. 3 and the aligner 150 controls the location at which the laser beam is to be applied.

### 3. Manufacturing Method for Third Embodiment

Next, a manufacturing method for a third embodiment of the invention will be described.

(1) Back Surface Grinding Step

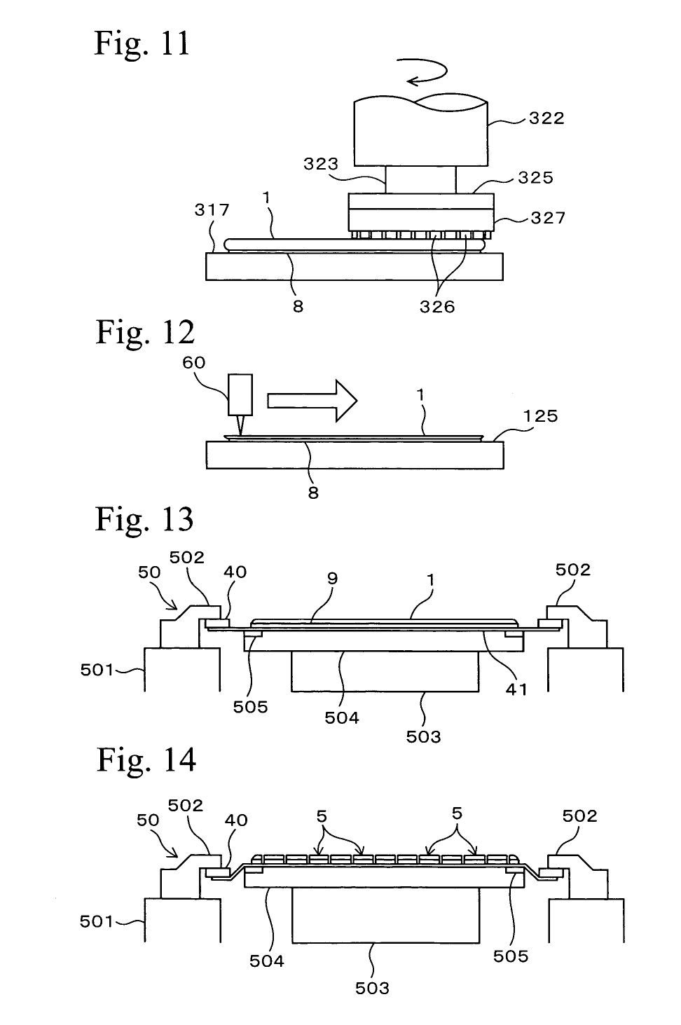

First, the back surface of the wafer 1 shown in FIG. 1 is ground until the wafer 1 becomes as thin as the chip 6 to be obtained. For this purpose, as shown in FIG. 11, the wafer 1 on the front surface of which the protection film 8 has been adhered is suctioned and held on the chuck table 317 of the grinding device 30 shown in FIG. 7 with the back surface of the wafer 1 facing up and the back surface is ground with the grindstones 326 of the grinding wheel 327.

(2) Inside Modified Layer Forming Step

Then, the laser beam is applied to the insides of the streets 2 of the wafer 1 along the streets 2 to change the portion to which the laser beam is applied into the inside modified layer. This inside modified layer is a layer that has been melted and set again so that the layer is reduced in strength. The layer is modified so as to break when external force is applied to it. In order to form the inside modified layer, as shown in FIG. 12, the wafer 1 is drawn and held on the chuck table 125 of the dicing device 10 shown in FIG. 3 with its back surface facing up, and the laser beam is applied to the wafer 1 from the laser beam irradiation device 60 mounted in place of the cutting blade 142. A position to which the laser beam is applied is controlled by the above aligner 150.

(3) Adhesive Film Adhering Step

Similarly to the adhesive film adhering step in the first embodiment, the adhesive film 9 and the dicing tape 41 are adhered on the back surface of the wafer 1 in which the inside modified layer is formed along the streets 2 as shown in FIG. 13.

(4) Dividing Step

Next, a dividing step for simultaneously dividing the wafer 1 into plural chips 6 and dividing the adhesive film 9 so that the separated films correspond to the chips 6 to thereby obtain the individual semiconductor chips 5 is carried out by utilizing the dividing device 50 used in the first embodiment. For this purpose, as shown in FIG. 13, the wafer 1 is placed on the chuck table 504 with the dicing tape 41 side facing down and is positioned under the retaining chips 502. Then, the protection film 8 adhered on the front surface is peeled off and removed. From this state, the wafer 1 is raised by the raising and lowering mechanism 503.

As a result, as shown in FIG. 14, the frame 40 is retained by the retaining chips 502 and the dicing tape 41 on the inside of the frame 40 moves up to thereby radially stretch the dicing tape 41 from the center. As the dicing tape 41 is stretched, the wafer 1 is broken at the inside modified layer thereof and is divided into chips 6. Moreover, as the dicing tape 41 is stretched, the adhesive film 9 between the chips 6 is pulled and is cut between the chips 6. Division of the wafer 1 into the chips 6 and cutting of the adhesive film 9 may occur simultaneously, or the adhesive film 9 may be cut after division of the wafer 1 into the chips 6.

With the above second and third embodiments, similarly to the first embodiment, the semiconductor chip 5 with a two-layered structure in which the adhesive film 9 is adhered on the entire back surface of the chip 6 as shown in the enlarged portion of FIG. 9 can be obtained. Therefore, the obtained semiconductor chip 5 has similar effects of prevention of damage to the chip 6 due to filling of the mold and occurrence of electrical problems in the stacked state.

What is claimed is:

1. A device with a two-layered structure, comprising: a chip having a functional element on a front surface of the chip; and
an adhesive film adhered on a back surface of the chip,
the adhesive film corresponding to at least the back surface of the chip and covering the entire back surface of the chip, an outer periphery of the chip not protruding from an outer periphery of the adhesive film.

2. The device according to claim 1, wherein the adhesive film is larger than the back surface of the chip and has an extra portion extending from an edge of the back surface.

3. A manufacturing method for the device according to claim 1, the method comprising:
a division groove forming step for forming a division groove in a front surface of a wafer along a predetermined division line, the division groove having a depth corresponding to a thickness of the chip to be obtained;
a protection film adhering step for adhering a protection film on the front surface of the wafer;
a back surface grinding step for grinding a back surface of the wafer until the division groove appears to divide the wafer into individual chips;
an adhesive film adhering step for adhering the adhesive film on a back surface of the wafer divided into plural chips and adhering a dicing tape on the adhesive film, the dicing tape supported by an annular frame and being extensible; and
an adhesive film cutting step for stretching the dicing tape while retaining the frame to thereby cut the adhesive film along the division groove.

4. A manufacturing method for the device according to claim 1, the method comprising:
a division groove forming step for forming a division groove in a front surface of a wafer along a predetermined division line, the division groove having a depth corresponding to a thickness of the chip to be obtained;
a protection film adhering step for adhering a protection film on the front surface of the wafer;
a back surface grinding step for grinding a back surface of the wafer until the division groove appears to divide the wafer into the individual chips;
an adhesive film adhering step for adhering the adhesive film on a back surface of the wafer divided into plural chips and adhering a dicing tape on the adhesive film, the dicing tape supported by an annular frame and being extensible; and
an adhesive film cutting step for applying a laser beam to the adhesive film through the division groove to thereby cut the adhesive film along the division groove.
